(19) United States
(12) Patent Application Publication
(10) Pub. No.: US 2014/0035086 A1
(43) Pub. Date: Feb. 6, 2014

(54) SOLID-STATE IMAGE SENSOR

(71) Applicant: Taro Kato, (US)

(72) Inventor: Taro Kato, Kawasaki-shi (JP)

(73) Assignee: CANON KABUSHIKI KAISHA, Tokyo (JP)

(21) Appl. No.: 14/113,435

(22) PCT Filed: Aug. 21, 2012
(86) PCT No.: PCT/JP2012/071527

§ 371 Date: Oct. 23, 2013

(30) Foreign Application Priority Data
Sep. 1, 2011 (JP) 2011-191074
Aug. 10, 2012 (JP) 2012-178923

(51) Int. Cl. H01L 27/146

(52) U.S. Cl. CPC H01L 27/14636; H01L 27/14629
USPC 257/432

(57) ABSTRACT

A solid-state image sensor includes a semiconductor layer having photoelectric conversion portions, and a wiring structure arranged on a side of a first face of the semiconductor layer, and receives light from a side of a second face of the semiconductor layer. The wiring structure includes a reflection portion having a reflection surface reflecting light transmitted through the semiconductor layer from the second face toward the first face, toward the semiconductor layer, and an insulation film located between the reflection surface and the first face. The sensor includes a first dielectric film arranged to contact the first face, and a second dielectric film arranged between the insulation film and the first dielectric film and having a refractive index different from refractive indices of the first dielectric film and the insulation film.

### TECHNICAL FIELD

The present invention relates to a solid-state image sensor.

### BACKGROUND ART

U.S. Pat. No. 7,755,123 describes a backside illuminated imaging device in which the thickness of a substrate is reduced to allow a photosensor to easily detect light incident on a back surface. FIG. 8 appended to this specification quotes a backside illuminated imaging device described in FIG. 1C of U.S. Pat. No. 7,755,123. The imaging device described in U.S. Pat. No. 7,755,123 includes a radiation reflector 128 that reflects photons, which are incident on and transmitted through a back surface of a semiconductor device substrate 104, toward a photosensor 110.

However, with the arrangement described in U.S. Pat. No. 7,755,123, photons reflected by the radiation reflector 128 toward the photosensor 110 are reflected toward the radiation reflector 128 by a front side 106f as an interfacial surface between the semiconductor device substrate 104 and a dielectric layer 118. Therefore, multiple reflections occur between the interfacial surface 106f and radiation reflector 128. Also, when a distance between the interfacial surface 106f and radiation reflector 123 is not uniform over an image sensing surface, the amount of photons which return to the photosensor 110 varies, thus causing sensitivity variations.

### SUMMARY OF INVENTION

The present invention provides a technique advantageous to improve sensitivity and to eliminate sensitivity variations.

One of the aspects of the present invention provides a solid-state image sensor, which includes a semiconductor layer having a plurality of photoelectric conversion portions, and a wiring structure arranged on a side of a first face of the semiconductor layer, and receives light from a side of a second face of the semiconductor layer, wherein the wiring structure includes a reflection portion having a reflection surface that reflects light, which is transmitted through the semiconductor layer from the second face toward the first face, toward the semiconductor layer, and an insulation film located between the reflection surface and the first face, and the solid-state image sensor comprises a first dielectric film arranged to contact the first face, and a second dielectric film which is arranged between the insulation film and the first dielectric film and has a refractive index different from refractive indices of the first dielectric film and the insulation film.

Further features of the present invention will become apparent from the following description of exemplary embodiments (with reference to the attached drawings).

### BRIEF DESCRIPTION OF DRAWINGS

FIGS. 1A and 1B are views illustrating the arrangement of a solid-state image sensor according to the first embodiment;

FIG. 2 is a view illustrating the arrangement of the solid-state image sensor according to the first embodiment;

FIG. 3 is a view illustrating the functions of the solid-state image sensor according to the first embodiment;

FIG. 4 is a graph exemplifying the wavelength dependence of a reflectance of a first face;

FIG. 5 is a graph exemplifying the reflectance of a reflection structure portion;

FIG. 6 is a graph exemplifying the relationship between the reflectance of a surface including a reflection surface and that of the reflection structure portion;

FIG. 7 is a view illustrating the arrangement of a solid-state image sensor according to the second embodiment; and

FIG. 8 is a view for explaining a solid-state imaging device described in U.S. Pat. No. 7,755,123.

### DESCRIPTION OF EMBODIMENTS

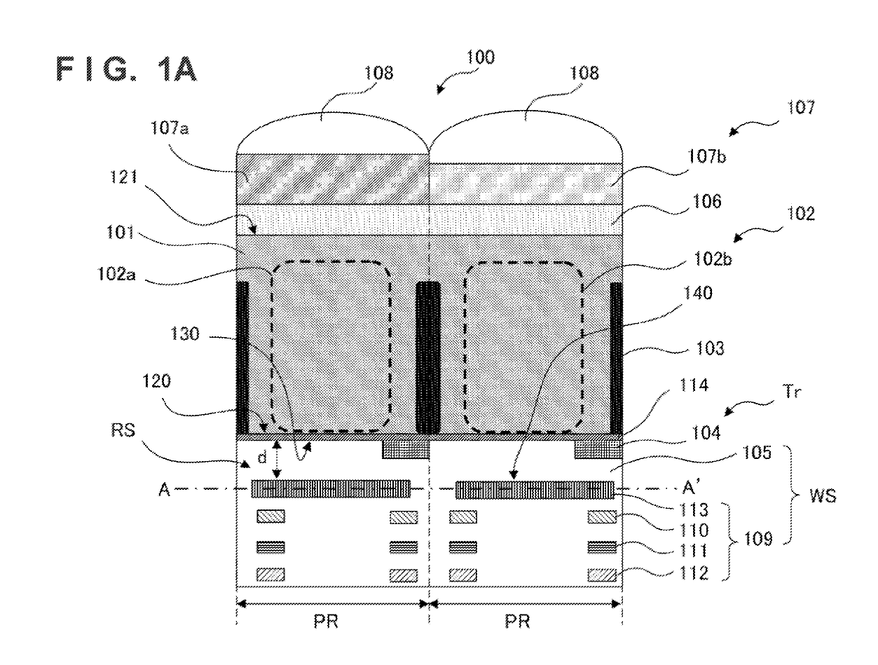

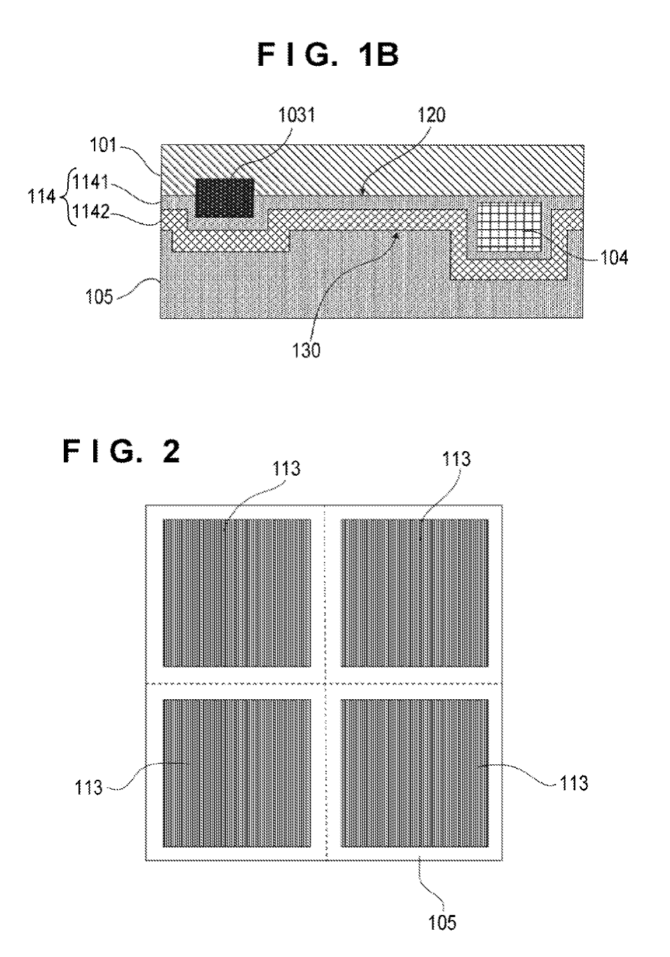

A solid-state image sensor 100 according to the first embodiment of the present invention will be described below with reference to FIGS. 1A and 1B, and FIG. 2 to FIG. 6. FIG. 1A is a sectional view of the solid-state image sensor 100 taken along a plane perpendicular to its image sensing surface, and illustrates only two pixels for the sake of simplicity. Note that the image sensing surface is a surface on which a pixel array is arranged. The pixel array is formed by arraying a plurality of pixels. FIG. 1B is an enlarged view of a section of an antireflection layer 114 of the solid-state image sensor 100 taken along a plane (different from FIG. 1A) perpendicular to its image sensing surface. FIG. 2 is a sectional view of the solid-state image sensor 100 taken along a A-A′ plane in FIG. 1A as a plane parallel to its image sensing surface. The solid-state image sensor 100 may be configured as, for example, a MOS image sensor or CCD image sensor.

The solid-state image sensor 100 has a semiconductor layer 101 having a first face 120 and second face 121. The semiconductor layer 101 may be configured by, for example, a silicon substrate. The solid-state image sensor 100 further has a wiring structure WS which is arranged on the side of the first face 120 of the semiconductor layer 101, and a color filter layer 107 which is arranged on the side of the second face 121 of the semiconductor layer 101. The color filter layer 107 may include a first color filter 107a, second color filter 107b, and third color filter 107c (not shown). In this case, the first color filter 107a may be a blue color filter, the second color filter 107b may be a green color filter, and the third color filter 107c may be a red color filter. The arrangement of the first, second, and third color filters 107a, 107b, and 107c may be defined by, for example, a Bayer matrix.

The solid-state image sensor 100 may further have a plurality of microlenses 108 arrayed on the color filter layer 107. The solid-state image sensor 100 may further have a planarization layer 106 between the second face 121 of the semiconductor layer 101 and the color filter layer 107. The planarization layer 106 may serve as, for example, an underlying film of the color filter layer 107. At an image sensing timing, light becomes incident on photoelectric conversion portions 102 via the microlenses 108. In this case, each microlens 108 is arranged on the side of the second face 121 of the semiconductor layer 101, and the wiring structure WS is arranged on the side of the first face 120 of the semiconductor layer 101. The solid-state image sensor which is configured to receive light from the side of the second face opposite to the side of the first face on which wiring structure is arranged may be called a backside illuminated solid-state image sensor.

A plurality of photoelectric conversion portions 102 are formed in the semiconductor layer 101. The semiconductor layer 101 and each photoelectric conversion portion 102 are formed of impurity semiconductor regions of opposing conductivity types, and they form a p-n junction (photodiode). The photoelectric conversion portion 102 is a region where carriers having the same polarity as that of charges to be read out as a signal are majority carriers. In the semiconductor layer 101, an element isolation portion 103 which isolates the neighboring photoelectric conversion portions 102 from each other may be formed. The element isolation portion 103 may have an impurity semiconductor region having a conductivity type opposite to that of the photoelectric conversion portion 102 and/or an insulator. In this case, the insulator may be LOCOS isolation, STI isolation, or the like.

An image sensing region of the solid-state image sensor 100 is configured by a plurality of pixel regions PR which are arrayed in a grid pattern without any gap is formed between the plurality of pixel regions PR, and each of the plurality of photoelectric conversion portions 102 is arranged on corresponding one of the plurality of pixel regions PR. Each pixel region PR is defined such that an area of each pixel region PR has a value obtained by dividing an area of the image sensing region by the number of pixels (the number of photoelectric conversion portions 102).

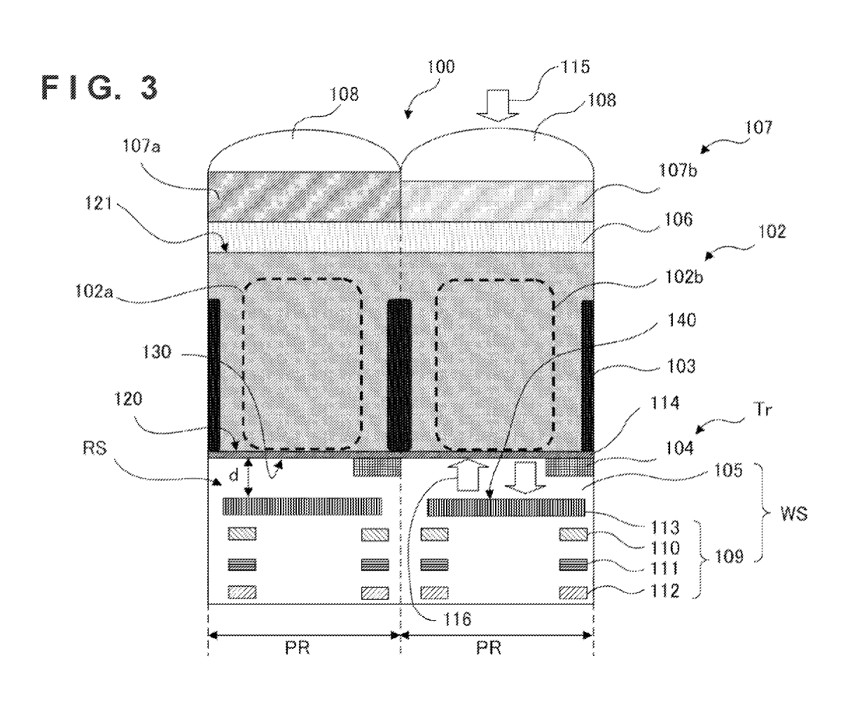

The solid-state image sensor 100 further includes a plurality of transistors Tr formed on the first face 120 of the semiconductor layer 101 so as to read out signals of the photoelectric conversion portions 102. Each transistor Tr includes a gate electrode 104 made up of, for example, polysilicon. In FIGS. 1A and 3, a source, drain, gate oxide film, and the like which form the transistor Tr are not shown. When the solid-state image sensor 100 is configured as a MOS image sensor, the plurality of transistors Tr may include, for example, transfer transistors required to transfer charges accumulated on the photoelectric conversion portions 102 to floating diffusions (not shown).

The wiring structure WS includes a stacked wiring portion 109 and interlayer dielectric film 105. The stacked wiring portion 109 may include a first wiring layer including a reflection portion 113 having a reflection surface 140, a second wiring layer 110, a third wiring layer 111, and a fourth wiring layer 112. The interlayer dielectric film 105 may be formed of, for example, a silicon oxide film. The interlayer dielectric film 105 includes a portion between the reflection surface 140 and first face 120. The reflection surface 140 reflects, toward the photoelectric conversion portion 102, light which is transmitted through the color filters 107a, 107b, and 107c, is incident on the photoelectric conversion portion 102, is transmitted through the photoelectric conversion portion 102, and is further passed through the first face 120. The reflection portion (first wiring layer) 113, second wiring layer 110, third wiring layer 111, and fourth wiring layer 112, which form the stacked wiring portion 109, may contain, for example, one of aluminum, copper, and tungsten as a major component.

Using a portion of the wiring layers which form the stacked wiring portion 109 as the reflection portion 113, the need for an additional layer required to form a wiring portion may be obviated. By forming the reflection portion 113 by the first wiring layer, which is closest to the first face 120 of the semiconductor layer 101, of the plurality of wiring layers that form the stacked wiring portion 109, a distance between the reflection surface 140 and photoelectric conversion portion 102 may be shortened, thus eliminating stray light. As a result, the sensitivity may be improved, and mixture of colors may be eliminated.

The solid-state image sensor 100 includes the antireflection layer 114, which is arranged to contact the first face 120 so as to eliminate reflection of light on the first face 120. The antireflection layer 114 may be formed of, for example, a plurality of dielectric films. Since the antireflection layer 114 is included, light reflected by the reflection portion 113 toward the photoelectric conversion portion 102 may be suppressed from being reflected by the first face 120 again. Thus, light of a larger amount may be returned by the reflection portion 113 to the photoelectric conversion portion 102 than a case without any antireflection layer 114.

FIG. 1B shows an arrangement example of the antireflection layer 114. The plurality of dielectric films which form the antireflection layer 114 may include a first dielectric film 1141 which is arranged to contact the first face 120, and a second dielectric film 1142 having a refractive index different from that of the first dielectric film 1141. In FIG. 1B, the first and second dielectric films 1141 and 1142 are in contact with each other, but another dielectric film may be arranged between the first and second dielectric films 1141 and 1142. The first and second dielectric films 1141 and 1142 may have refractive indices lower than that of the semiconductor layer 101. The second dielectric film 1142 may have a refractive index higher than that of the first dielectric film 1141. Also, the second dielectric film 1142 may have a refractive index higher than that of the interlayer dielectric film 105. The first dielectric film 1141 may have a refractive index equal to a refractive index of the interlayer dielectric film 105. The refractive indices of the first dielectric film 1141 and interlayer dielectric film 105 may be equal to each other or different from each other.

At least one or, preferably, both of the first and second dielectric films 1141 and 1142 may have a thickness smaller than that of the interlayer dielectric film 105. The thickness of the antireflection layer 114, which thickness is equal to or larger than the sum of the thicknesses of the first and second dielectric films 1141 and 1142, may be smaller than a thickness of the interlayer dielectric film 105. Note that the thickness of the interlayer dielectric film 105 indicates a thickness of a portion, which is located between the second face 120 and reflection surface 140, of the interlayer dielectric film 105. The thicknesses of the first and second dielectric films 1141 and 1142 may be equal to each other or different from each other. When the second and first dielectric films 1142 and 1141 have different thicknesses, the performance of an antireflection function mainly depends on the refractive index of the thicker film. When the thickness of the second dielectric film 1142 is set to be larger than a thickness of the first dielectric film 1141, and the second dielectric film 1142 has a refractive index higher than a refractive index of the first dielectric film 1141, the antireflection effect may be improved.

Absorption of light by the semiconductor layer 101 and effects of the reflection portion (first wiring layer) 113 and antireflection layer 114 will be described below under the assumption that the thickness of the semiconductor layer 101 is 3 μm, so as to provide a practical example. A ratio of absorption of light, which is incident on the second face 121, by the semiconductor region between the second face 121 and first face 120 (a ratio to light incident on the second face 121) is different depending on wavelengths of light. A case will be examined below wherein light is perpendicularly incident on the second face 121. In this case, until light passed through the second face 121 reaches the first face 120, most of light rays of a wavelength of 450 nm, which are transmitted through the blue color filter 107a, are absorbed. On the other hand, about 87% of light rays of a wavelength of 550 nm, which are transmitted through the green color filter 107b, is absorbed. Also, about 70% of light rays of a wavelength of 620 nm, which are transmitted through the red color filter 107c, is absorbed. At this time, as illustrated in FIG. 3, light rays 116, which are not absorbed, are reflected by the reflection portion 113 toward the first face 120. The antireflection layer 114 may have an arrangement in which a 10 nm thick silicon oxide film as the first dielectric film 1141 and a 50 nm thick silicon nitride film as the second dielectric film 1142 are arranged in turn on the first face 120. FIG. 4 exemplifies the wavelength dependence of the reflectance of the first face 120 in a case in which the antireflection layer 114 is formed on the first face 120 (solid curve) and that without any antireflection layer 114 (broken curve). In FIG. 4, the abscissa plots the wavelength of light, and the ordinate plots the reflectance of the first face 120.

In the case without any antireflection layer 114, when light reflected by the reflection surface 140 of the reflection portion 113 reaches the first face 120, it is reflected by the first face 120, and is further reflected by the reflection surface 140. By repeating such reflections, multiple reflections occur between the reflection surface 140 and first face 120. Let λ be the wavelength of light, d be the distance (thickness of a medium) between the upper surface 130 of the interlayer dielectric film 105 and the reflection surface 140, and n be the refractive index of the interlayer dielectric film 105 as a medium between the upper surface 130 and reflection surface 140. Also, let R₁ be a reflectance of the first face 120, R₂ be a reflectance of a plane which includes the reflection surface 140 and is parallel to the first face 120, and R be a reflectance of the reflection structure portion RS including the first face 120 and refection surface 140. Since multiple reflections of light occur between the reflection surface 140 and first face 120, the reflectance R depends on λ, d, n, R₁, and R₂. The reflectance R may be expressed by:

$$R = \frac{{R}_{1} + {R}_{2} - 2 \sqrt{{R}_{1} \cdot {R}_{2}} cos ( \frac{4 π}{λ} nd )}{1 + {R}_{1} \cdot {R}_{2} - 2 \sqrt{{R}_{1} \cdot {R}_{2}} cos ( \frac{4 π}{λ} nd )} \qquad ( 1 )$$

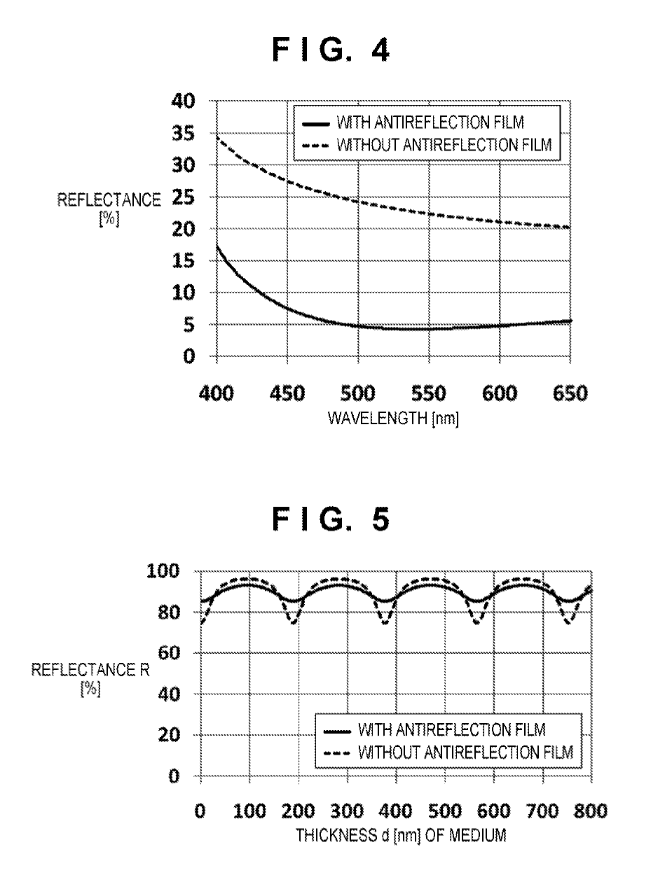

FIG. 5 exemplifies the reflectance R of the reflection structure portion RS. The abscissa plots the thickness d of the medium, and the ordinate plots the reflectance R. Also, the solid curve represents the reflectance R when the antireflection layer 114 is included, and the broken curve represents the reflectance R when the antireflection layer 114 is not included. In this example, the reflectance R₂ is 90%, and the wavelength λ of light is 550 nm. As may be seen from FIG. 5, when the antireflection layer 114 is formed on the first face 120, a change in reflectance R caused by a change in thickness d of the medium is smaller than the case without any antireflection layer 114. Therefore, by forming the antireflection layer 114, a change in amount of light returned to the photoelectric conversion portion 102 by the reflection structure portion RS may be reduced. Thus, sensitivity variations caused by nonuniformity of the thickness d of the medium, that is, nonuniformity of the distance between the first face 120 and reflection portion 113 may be eliminated.

In the example shown in FIG. 5, the reflectance R₂ is 90%. However, the reflectance R₂ need only assume a value which may make the reflectance R of the reflection structure portion RS be equal to or larger than zero. When the reflectance R is zero, no light returns to the photoelectric conversion portion 102, and sensitivity improvement may not be expected.

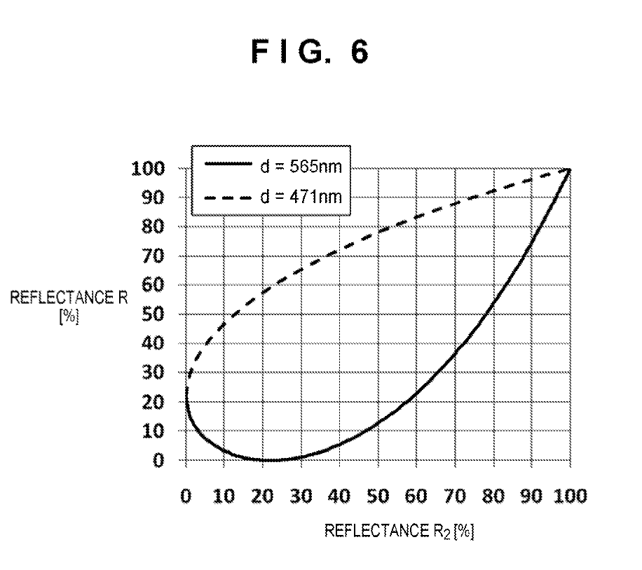

The relationship between the reflectances R and R₂ will be described below. FIG. 6 exemplifies the relationship between the reflectances R and R₂. In FIG. 6, the wavelength λ of light is 550 nm, and the refractive index n of the interlayer dielectric film 105 is 1.46. Also, the reflectance R₁ of the first face 120 is 221 as a reflectance at λ=550 nm when no antireflection layer 114 is included (see FIG. 4).

From equation (1), when the thickness d of the medium corresponds to an even multiple of λ/4n (=94.2 nm), the reflectance R of the reflection structure portion RS assumes a minimum value; when the thickness d corresponds to an odd multiple of λ/4n, the reflectance R assumes a maximum value. FIG. 6 shows the solid curve which represents the reflectance R when the thickness d is 565 nm as an even multiple of λ/4n, and the broken curve which represents the reflectance R when the thickness d is 471 nm as an odd multiple of λ/4n. As shown in FIG. 6, when the thickness d of the medium is 565 nm, a value of the reflectance R₂, which makes the reflectance R of the reflection structure portion RS be zero, exists. This means that light reflected by the first face 120 and that reflected by the reflection portion 113 cancel each other. The reflectance R₁ may assume various values depending on the arrangement of the antireflection layer 114.

From FIG. 6 and equation (1), when the reflectances R₁ and R₂ satisfy R₂>R₁, [reflectance R>0] may be set. This does not depend on the wavelength λ and the refractive index n of the interlayer dielectric film 105. That is, when the reflectance R₂ is larger than a maximum value of the reflectance R₁, R>0 holds to improve the sensitivity. In this case, the reflectance R₁ assumes the maximum value when no antireflection layer 114 is formed on the first face 120. The broken curve in FIG. 4 represents the reflectance when no antireflection layer 114 is formed on the first face 120. As may be seen from FIG. 4, a reflectance at a short wavelength (blue) is high. Almost of light rays in a blue range which are transmitted through the blue color filter 107a do not reach the first face 120, and are photoelectrically converted by the photoelectric conversion portion 102, light rays which are transmitted through the green color filter 107b and red color filter 107c need only be considered. Hence, the wavelength λ to be considered may be about 480 nm or higher. When λ=480 nm, the reflectance R₁ when no antireflection layer 114 is formed on the first face 120 is 25% (see FIG. 4).

The reflectance R₂ of the plane which includes the reflection surface 140 of the reflection portion 113 and is parallel to the first face 120 depends on the material of the interlayer dielectric film 105, the material of the reflection portion 113, and a ratio of an area of the reflection surface 140 to an area of the pixel region PR. Letting R₀ be a reflectance of the reflection surface 140 (this reflectance is decided based on the material of the reflection portion 113 and the material of the interlayer dielectric film 105), and S be a ratio of an area of the reflection surface 140 in one pixel region PR to an area of one pixel region PR on the plane parallel to the first face 120, [reflectance R₂=R₀·S] holds.

Therefore, the reflectance R of the reflection structure portion RS may be set to be larger than zero if inequality (2) is satisfied:

R₂=R₀·S>0.25 (2)

When the reflectance portion 113 is formed of aluminum, and the interlayer dielectric film 105 is formed of a silicon oxide, the reflectance R₀ of the interfacial surface between the reflection portion 130 and interlayer dielectric film 105, that is, the reflection surface 140 is about 90%. In this case, when the ratio of the area of the reflection surface 140 in one pixel region RP to the area of one pixel region PR on the plane parallel to the first face 120 is set to be 27.8% or more, inequality (2) may be satisfied. As a result, the reflectance R of the reflection structure portion RS becomes larger than zero, and the sensitivity may be improved.

As described above, by forming the antireflection layer 114 on the first face 120, multiple reflections between the first face 120 and reflection surface 140 may be eliminated, thus improving the sensitivity. Also, sensitivity nonuniformity may be eliminated since the multiple reflections are eliminated.

In the above example, the thickness of the semiconductor layer 101 is 3 μm. However, the thickness of the semiconductor layer 101 may be, for example, 2 μm or more. The shape of the reflection surface 140 of the reflection portion 113 may be a concaved surface shape so that light is condensed on the corresponding photoelectric conversion portion 102. In the above example, the reflection portion 113 is formed on the first wiring layer closest to the first face 120, but it may be formed on another wiring layer. Also, the reflection portion may be formed on a layer other than layers formed for the purpose of wirings. In this case, since a material used to form the reflection portion may be freely selected, it is advantageous to improve the reflectance. As a major component of the material used to form the reflection portion, a material other than aluminum, copper, and tungsten may be used. The reflection portion may be formed using a plurality of dielectric films. Alternatively, the reflection portion may be formed as a vacuum space or a space filled with a gas. By setting a focal point position of each microlens at a position between the first face 120 and reflection portion 113, spread of light reflected by the reflection portion 113 may be suppressed. Thus, a high ratio of light, which is reflected by the reflection portion 113 and is returned to the photoelectric conversion portion 102, may be set, thus improving the sensitivity. Also, an antireflection layer may be formed on the second face 121, thereby increasing an amount of light which is incident on the semiconductor layer 101.

Other details will be described below with reference to FIG. 1B. The second dielectric film 1142 may have a portion located between the gate electrode 104 and interlayer dielectric film 105. The first dielectric film 1141 may have a portion located between the gate electrode 104 and interlayer dielectric film 105. The portions, which are located between the gate electrode 104 and interlayer dielectric film 105, of the respective dielectric films may eliminate reflection of light by the surface of the gate electrode 104. The portions, which are located between the gate electrode 104 and interlayer dielectric film 105, of the respective dielectric films and portions, which cover the photoelectric conversion portion 102, of the respective dielectric films may have different thicknesses. The first dielectric film 1141 may have a portion located between the gate electrode 104 and semiconductor layer 101. This portion may serve as a gate insulation film. The first dielectric film 1141 may be formed before and after formation of the gate electrode 104, so as to have the portion located between the gate electrode 104 and interlayer dielectric film 105 and that located between the gate electrode 104 and semiconductor layer 101.

FIG. 1B exemplifies an insulator 1031 included in the element isolation portion 103. In FIG. 1B, the insulator 1031 protrudes from the first face 120. The typical insulator 1031 formed in the element isolation portion 103 is silicon oxide. The second dielectric film 1142 may have a portion located between the insulator 1031 and interlayer dielectric film 105. Also, the first dielectric film 1141 may have a portion located between the insulator 1031 and interlayer dielectric film 105. The portions, which are located between the insulator 1031 and interlayer dielectric film 105, of the respective dielectric films may eliminate reflection of light by the first face 120 of the semiconductor layer 101. Especially, when the insulator 1031 of the element isolation portion 103 protrudes from the first face 120, interference components of light between the reflection surface 140 and first face 120 are eliminated in the vicinity of the insulator 1031, thereby eliminating sensitivity nonuniformity. When the insulators 1031 form a periodic three-dimensional structure over a plurality of pixel regions, the sensitivity nonuniformity may be eliminated more.

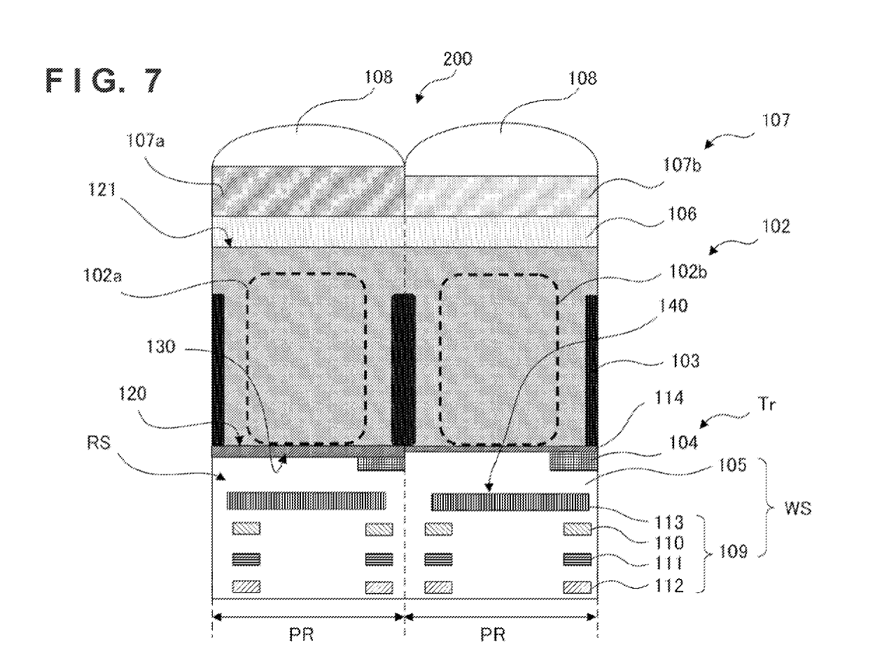

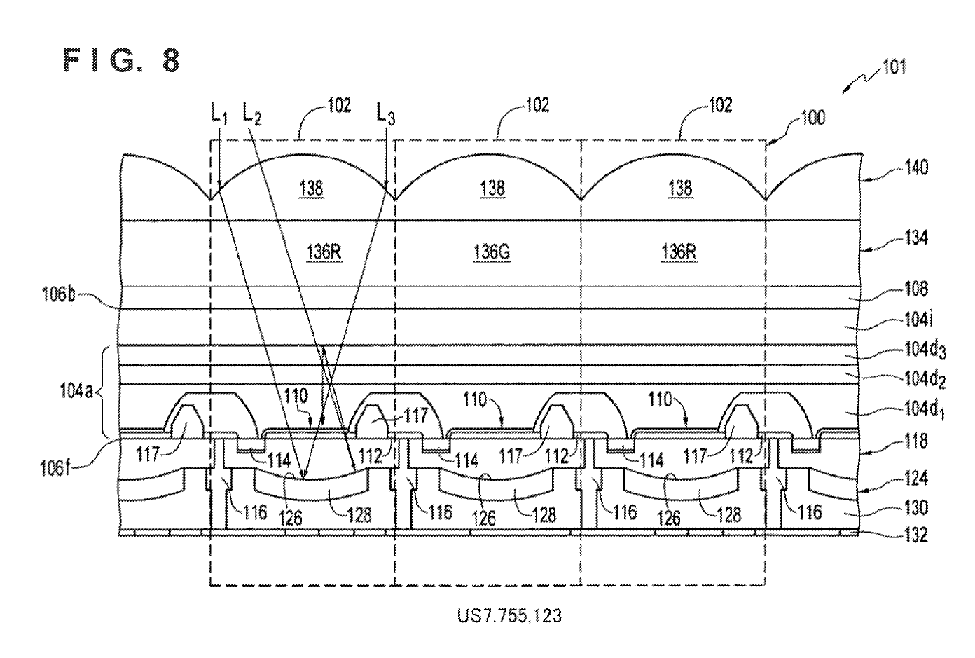

A solid-state image sensor 200 according to the second embodiment of the present invention will be described below with reference to FIG. 7. Items which are not mentioned in this embodiment may follow the first embodiment. In the second embodiment, an antireflection film 214, which is arranged to contact a first face 120, has a plurality of portions respectively corresponding to a plurality of color filters 107a, 107b, and 107c, and these portions have thicknesses according to colors of the corresponding color filters. Thus, the sensitivity of a pixel of each color may be improved.

Let λ₁, λ₂, and λ₃ be wavelengths at which the first, second, and third color filters 107a, 107b, and 107c exhibit maximum transmittances, and m be a refractive index of silicon nitride. The antireflection film 214 includes a first portion formed in a pixel including the first color filter 107a, a second portion formed in a pixel including the second color filter 107b, and a third portion formed in a pixel including the third color filter 107c. The first portion may include a 10 nm thick silicon oxide film formed on the first face 120, and a λ₁/4 m thick silicon nitride film formed on that silicon oxide film. The second portion may include a 10 nm thick silicon oxide film formed on the first face 120, and a λ₂/4 m thick silicon nitride film formed on that silicon oxide film. The third portion may include a 10 nm thick silicon oxide film formed on the first face 120, and a λ₃/4 m thick silicon nitride film formed on that silicon oxide film.

For example, assume that the wavelengths λ₁, λ₂, and λ₃ of the maximum transmittances of the color filters of red (R), green (G), and blue (B) pixels are respectively 610 nm, 530 nm, and 450 nm, and the refractive index m of the silicon nitride is 2.0. At this time, the preferred thicknesses of the antireflection films 214 (first, second, and third portions) of the red (R), green (G), and blue (B) pixels are respectively 76 nm, 66 mm, and 56 nm.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-191074, filed Sep. 1, 2011, and No. 2012-178923, filed Aug. 10, 2012, which are hereby incorporated by reference herein in their entirety.

1. A solid-state image sensor, which includes a semiconductor layer having a plurality of photoelectric conversion portions, and a wiring structure arranged on a side of a first face of the semiconductor layer, and receives light from a side of a second face of the semiconductor layer, wherein
the wiring structure includes a reflection portion having a reflection surface that reflects light, which is transmitted through the semiconductor layer from the second face toward the first face, toward the semiconductor layer, and an insulation film located between the reflection surface and the first face, and
the solid-state image sensor comprises a first dielectric film arranged to contact the first face, and a second dielectric film which is arranged between the insulation film and the first dielectric film and has a refractive index different from refractive indices of the first dielectric film and the insulation film.

2. The sensor according to claim 1, wherein a plurality of pixel regions which are arranged in a grid pattern without any gaps between the plurality of pixel regions,
each of the plurality of photoelectric conversion portions is arranged in a corresponding pixel region of the plurality of pixel regions, and
letting R₀ be a reflectance of the reflection surface, and S be an area of the reflection surface occupied in one pixel region in a plane parallel to the first face, the wiring structure satisfies:
R₀S>0.25.

3. The sensor according to claim 1, satisfying at least one of:
(1) the refractive index of the second dielectric film is higher than the refractive index of the first dielectric film;
(2) the refractive index of the second dielectric film is higher than the refractive index of the insulation film;
(3) the second dielectric film is thicker than the first dielectric film; and
(4) the first dielectric film and the second dielectric film are thinner than the insulation film.

4. The sensor according to claim 1, wherein a gate electrode of a transistor is formed between the first face and the insulation film, and the second dielectric film has a portion located between the gate electrode and the insulation film.

5. The sensor according to claim 4, wherein the first dielectric film includes a portion located between the gate electrode and the semiconductor layer.

6. The sensor according to claim 1, wherein the semiconductor layer includes an element isolation portion containing an insulator, and the second dielectric film includes a portion located between the element isolation portion and the insulation film.

7. The sensor according to claim 1, wherein the first dielectric film and the insulation film are made up of silicon oxide.

8. The sensor according to claim 1, wherein the second dielectric film is made up of silicon nitride.

9. The sensor according to claim 1, wherein the reflection portion is formed to have one of aluminum, copper, and tungsten as a major component, and has a reflectance by the reflection surface, which is higher than a reflectance by the first face.

10. The sensor according to claim 1, wherein the reflection surface forms a concave surface with respect to the first face.

11. The sensor according to claim 1, further comprising a plurality of color filters arranged on the side of the second face, wherein the second dielectric film has thicknesses according to colors of corresponding color filters.
